(19) United States
(12) Patent Application Publication
(10) Pub. No.: US 2025/0254791 A1
(43) Pub. Date: Aug. 7, 2025

(54) CIRCUIT BOARD

(71) Applicant: CHIPBOND TECHNOLOGY CORPORATION, Hsinchu (TW)

(72) Inventors: Shih-Chuan Lee, Kaohsiung City (TW); Ching-Chi Chan, Taichung City (TW); Tzu-Min Wu, Kaohsiung City (TW)

(21) Appl. No.: 18/678,028

(22) Filed: May 30, 2024

(30) Foreign Application Priority Data
Feb. 6, 2024 (TW) 113104828

(51) Int. Cl. H05K 1/02

(52) U.S. Cl. CPC H05K 1/0281; H05K 1/0253; H05K 1/0296

(57) ABSTRACT

A circuit board includes a substrate, circuit lines and a protective layer. The circuit lines are arranged on the substrate, and each includes a first conductive section, a second conductive section and a third conductive section, the second conductive section is located between the first and third conductive sections. The first and third conductive sections are covered by the protective layer, and the second conductive portion and an outer lead of the first conductive section are not covered by the protective layer. The protective layer covering the third conductive section is provided to protect the second conductive section and the outer lead from scratch or compression.

### CROSS-REFERENCE TO RELATED APPLICATIONS

This application claims priority to R.O.C Patent Application No. 113104828 filed Feb. 6, 2024, the disclosure of which is hereby incorporated by reference in its entirety.

### FIELD OF THE INVENTION

This invention relates to a circuit board, and more particularly to a flexible circuit board having circuit lines which are protected from scratch or compression by foreign matter.

### BACKGROUND OF THE INVENTION

Referring to FIG. 1, a conventional circuit tape T1 includes multiple units 10 each including a substrate 11, circuit lines 12 and a protective layer 13. Each of the circuit lines 12 has an inner lead 12a, an outer lead 12b and a test pad 12c, the outer lead 12b is located between the inner lead 12a and the test pad 12c. The protective layer 13 covers the circuit lines 12 except the inner lead 12a, the outer lead 12b and the test pad 12c.

During transporting or rolling up the circuit tape T1, the outer lead 12b and the test pad 12c which are not covered by the protective layer 13 may be scratched by foreign matter remained on the circuit tape T1 (not shown, e.g. metal particle/debris or ink particle/debris generated during manufacture processes), and they may be compressed to be deformed or generate whiskers to cause the unit 10 to be defective.

### SUMMARY OF THE INVENTION

One object of the present invention is to provide a circuit board which can prevent foreign matter remained on the circuit board from scratching circuit lines and can protect the circuit lines from compression to generate whiskers.

A circuit board of the present invention includes a substrate, circuit lines and a protective layer. A first area, a second area and a third area are defined on a surface of the substrate, and the second area is located between the first and third areas in a first direction for transportation the circuit board. Each of the circuit lines includes a first conductive section arranged on the first area, a second conductive section arranged on the second area and a third conductive section arranged on the third area. The first conductive section has an inner lead and an outer lead. The second conductive section is located between the first and third conductive sections and is connected to the outer lead and the third conductive section. The first and third conductive sections are covered by the protective layer, and the second conductive section, the inner lead and the outer lead of the first conductive section are not covered by the protective layer.

Owing to the protective layer covering the third conductive section is higher than the circuit lines, the outer lead of the first conductive section and the second conductive section which are not covered by the protective layer are protected from scratch by foreign matter and protected from compression to generate whiskers.

### BRIEF DESCRIPTION OF DRAWINGS

FIG. 1 is top view diagram illustrating a conventional circuit tape.

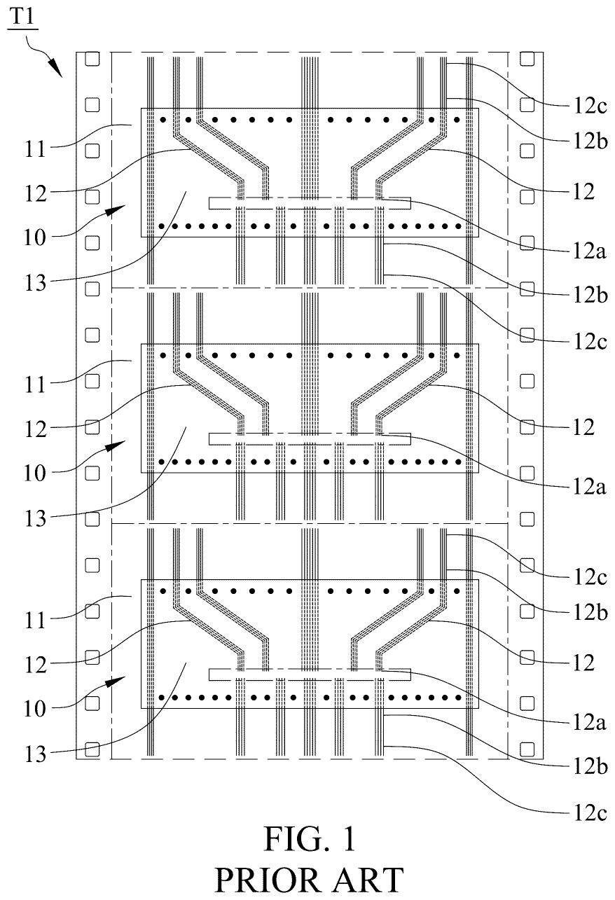

FIG. 2 is a top view diagram illustrating a circuit tape in accordance with one embodiment of the present invention.

FIG. 3 is a top view diagram illustrating a circuit board in accordance with one embodiment of the present invention.

FIG. 4A is a top view diagram illustrating a circuit board in accordance with one embodiment of the present invention.

FIG. 4B is a top view diagram illustrating a circuit board in accordance with another embodiment of the present invention.

FIG. 5 is a cross-section view diagram along A-A line of FIG. 3.

FIG. 6 is a cross-section view diagram illustrating a part of a circuit tape during rolling up in accordance with one embodiment of the present invention.

### DETAILED DESCRIPTION OF THE INVENTION

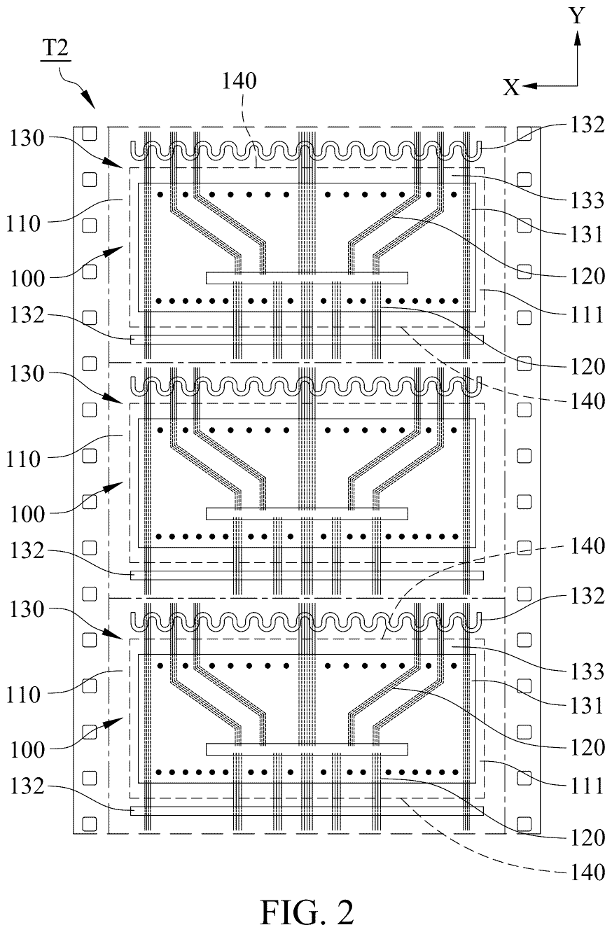

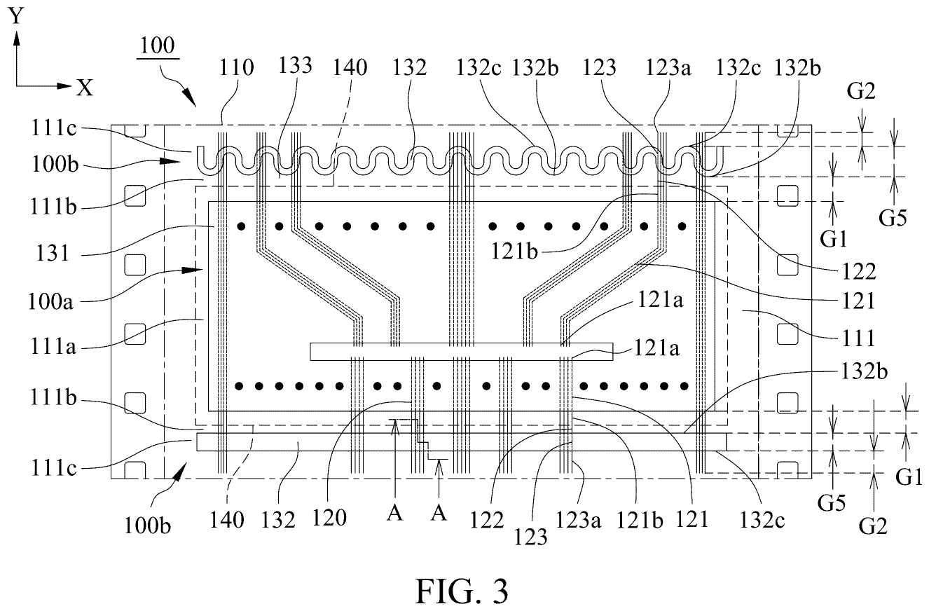

With reference to FIGS. 2 and 3, a circuit tape T2 includes a plurality of circuit boards 100 each including a substrate 110, circuit lines 120 and a protective layer 130. The substrate 110 can be made of polyimide (PI) or other suitable materials, and a first area 111a, a second area 111b and a second area 111c are defined on a surface 111 of the substrate 110. Along a first direction Y for transporting the circuit boards 100, the second area 111b is located between the first area 111a and the third area 111c.

With reference to FIGS. 2, 3 and 5, the circuit lines 120 are arranged on the surface 111 of the substrate 110 and they can be made of copper or other suitable metal materials. In this embodiment, each of the circuit lines 120 has a copper layer 120a and a tin layer 120b which covers the copper layer 120a. Each of the circuit lines 120 includes a first conductive section 121 located on the first area 111a, a second conductive section 122 located on the second area 111b and a third conductive section 123 located on the third area 111c, the second conductive section 122 is located between the first conductive section 121 and the third conductive section 123. One end of the first conductive section 121 is an inner lead 121a provided for bonding an electronic element (not shown, e.g. a chip), the other end of the first conductive section 121 is an outer lead 121b. The second conductive section 122 is connected to the third conductive section 123 and the outer lead 121b of the first conductive section 121. In this embodiment, the third conductive section 123 has a test pad 123a.

With reference to FIGS. 2 and 3, the protective layer 130 covers the first conductive section 121 and the third conductive section 123 of each of the circuit lines 120, but not cover the second conductive section 122, the inner leads 121a and the outer lead 121b of the first conductive section 121 and the test pad 123a of the third conductive section 123. Preferably, the protective layer 130 can be made of a solder resist material.

Referring to FIGS. 2 and 3, the protective layer 130 has a first protective portion 131, at least one second protective portion 132 and a hollow portion 133 which is located between the first protective portion 131 and the second protective portion 132. In this embodiment, the protective layer 130 has two second protective portions 132, and the first protective portion 131 is located between the two second protective portions 132.

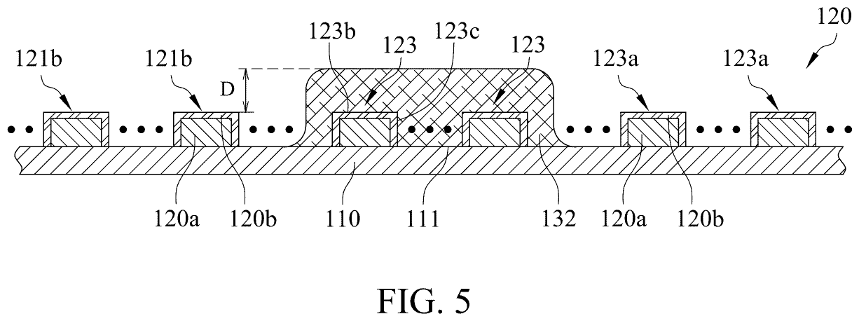

With reference to FIGS. 3 and 5, the first protective portion 131 covers the first conductive section 121 but not cover the inner lead 121a and the outer lead 121b of the first conductive section 121, the second protective portion 132 covers the third conductive section 123 but not cover the test pad 123a of the third conductive section 123. In this embodiment, the second protective portion 132 covers the tin layer 120b such that the tin layer 120b is located between the copper layer 120a and the second protective portion 132. The hollow portion 133 located between the first protective portion 131 and the second protective portion 132 is provided to expose the second conductive section 122 located between the first conductive section 121 and the third conductive section 123.

With reference to FIGS. 3 and 5, the second protective portion 132 covers a top surface 123b and a lateral surface 123c of the third conductive section 123 and covers the surface 111 of the substrate 110 where is located between the adjacent third conductive sections 123. A thickness D of the second protective portion 132 covering the top surface 123b of the third conductive section 123 is designed to be greater than or equal to 0.5 um and less than or equal to 50 um to allow the second protective portion 132 to be higher than the circuit lines 120.

As shown in FIG. 3, the outer lead 121b of the first conductive section 121, which is not covered by the first protective portion 131, is connected to the second conductive section 122 and visible from the hollow portion 133.

With reference to FIG. 3, a predetermined cutting line 140 is designed to run through the hollow portion 133 in a second direction X intersecting the first direction Y and be located between the first protective portion 131 and the second protective portion 132, and the outer lead 121b of the first conductive section 121 is located between the first protective portion 131 and the predetermined cutting line 140. In this embodiment, the first direction Y is vertical and the second direction X is horizontal, the predetermined cutting line 140 is designed to surround the first area 111a defined on the surface 111 of the substrate 110 to separate the circuit board 100 into a part 100a to be reserved and a part 100b to be removed. The first conductive section 121 and the first protective portion 131 covering the first conductive section 121 are arranged on the part 100a to be reserved. The second conductive section 122, the third conductive section 123 and the second protective portion 132 covering the third conductive section 123 are arranged on the part 100b to be removed. During cutting process, a cutting tool (not shown) is provided to cut the circuit board 100 along the predetermined cutting line 140 to divide the circuit board 100 into the part 100a to be reserved and the part 100b to be removed, and meanwhile, the first conductive section 121 and the second conductive section 122 of each of the circuit lines 120 are separated from each other, and the outer lead 121b of the first conductive section 121 is located on the part 100a to be reserved.

With reference to FIG. 3, a first distance G1 between the first protective portion 131 and the second protective portion 132 along the first direction Y is greater than or equal to 0.5 um and less than or equal to 2 um, and a second distance G2 between the second protective portion 132 and the test pad 123a of the second conductive section 123 along the first direction Y is greater than or equal to 0.5 um and less than or equal to 2 um.

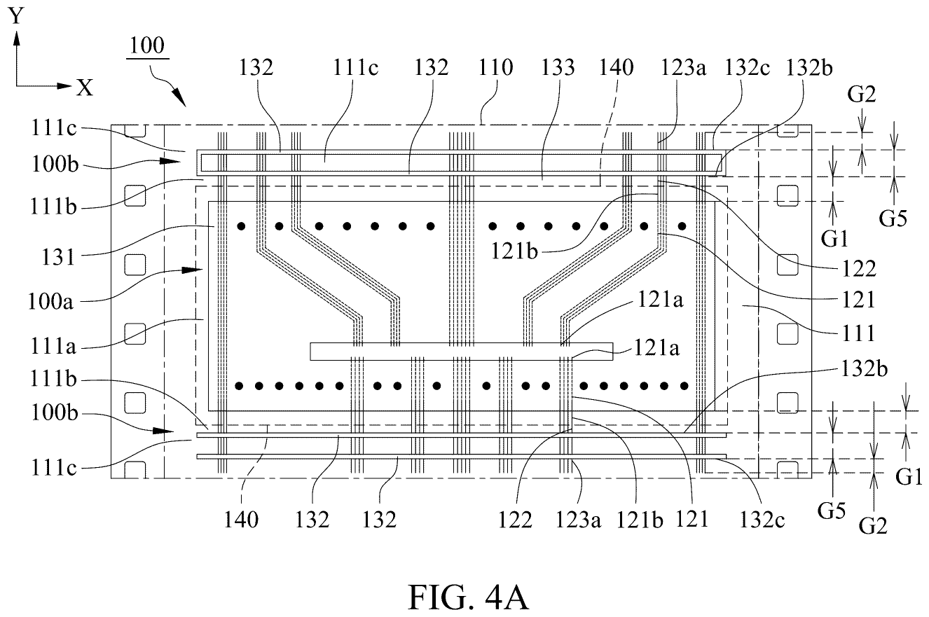

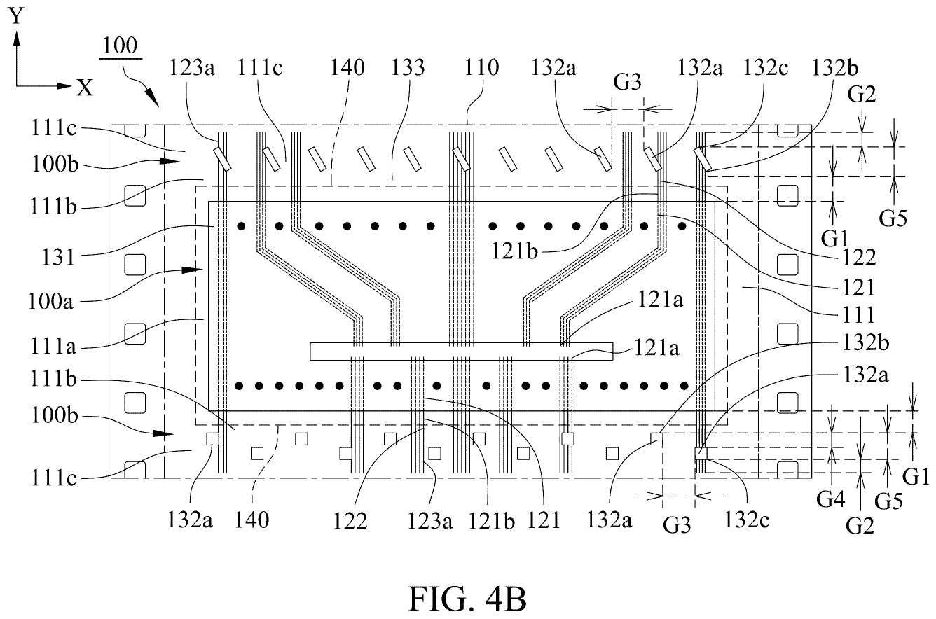

With reference to FIGS. 3 and 4A, the second protective portion 132 extends along the second direction X and has a continuous geometric form, e.g. linear, curved or square loop, regular or irregular geometric shape. In another embodiment as shown in FIG. 4B, the second protective portion 132 may have a non-continuous geometric form and involves multiple protrusions 132a which may be square, circular, regular or irregular geometric shape. A third distance G3 between the adjacent protrusions 132a along the second direction X is greater than or equal to 0.5 um and less than or equal to 158 mm. A fourth distance G4 between the adjacent protrusions 132a along the first direction Y is greater than or equal to 0.5 um and less than or equal to 50 mm. Referring to FIG. 3, the second protective portion 132 has a first edge 132b and a second edge 132c, and the first edge 132b is closer to the first protective portion 131 than the second edge 132c in the first direction Y. A fifth distance G5 from the first edge 132b to the second edge 132c is greater than or equal to 0.5 um and less than or equal to 50 mm.

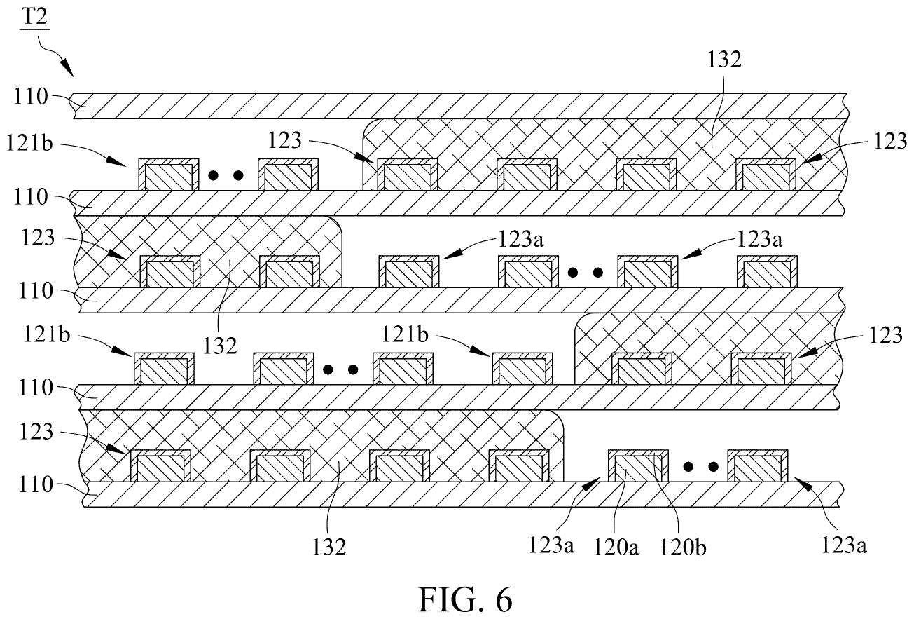

With reference to FIGS. 2, 3, 5 and 6, the second protective portion 132 provided on the third area 111c and the third conductive section 123 is higher than the circuit lines 120 so it can prevent foreign matter (not shown, such as metal particle, metal debris, ink particle or ink debris generated during manufacture processes) from scratching the outer lead 121b of the first conductive section 121, the second conductive section 122 and the test pad 123a of the third conductive section 123 during transporting or rolling up the circuit tape T2. Moreover, the second protective portion 132 can prevent the outer lead 121b of the first conductive section 121, the second conductive section 122 and the test pad 123a of the third conductive section 123 from being compressed to generate whiskers.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A circuit board comprising:
a substrate having a surface, a first area, a second area and a third area are defined on the surface, and the second area is located between the first and third areas in a first direction for transporting the circuit board;
a plurality of circuit lines each including a first conductive section arranged on the first area, a second conductive section arranged on the second area and a third conductive section arranged on the third area, the first conductive section includes an inner lead and an outer lead, the second conductive section is located between the first and third conductive sections and connected to the outer lead of the first conductive section and the third conductive section; and
a protective layer configured to cover the first and third conductive sections, wherein the second conductive section, the inner lead and the outer lead of the first conductive section are not covered by the protective layer.

2. The circuit board in accordance with claim 1, wherein the protective layer includes a first protective portion, at least one second protective portion and a hollow portion which is located between the first protective portion and the at least one second protective portion, the first protective portion is configured to cover the first conductive section, the inner lead and the outer lead of the first conductive section are not covered by the first protective portion, the at least one second protective portion is configured to cover the third conductive section, the hollow portion is configured to expose the outer lead of the first conductive section and the second conductive section, a predetermined cutting line is configured to run through the hollow portion and be located between the first protection portion and the at least one second protective portion to separate the circuit board into a part to be reserved and a part to be removed, the outer lead is located between the first protective portion and the predetermined cutting line, the first conductive section and the first protective portion covering the first conductive section are located on the part to be reserved, the second conductive section, the third conductive section and the at least one second protective portion covering the third conductive section are located on the part to be removed.

3. The circuit board in accordance with claim 2, wherein a test pad of the third conductive section is not covered by the at least one second protective portion.

4. The circuit board in accordance with claim 2, wherein the protective layer includes two second protective portions, and the first protective portion is located between the two protective portions.

5. The circuit board in accordance with claim 2, wherein a first distance between the first protective portion and the at least one second protective portion along the first direction is greater than or equal to 0.5 um and less than or equal to 2 um.

6. The circuit board in accordance with claim 5, wherein a test pad of the third conductive section is not covered by the at least one second protective portion, a second distance between the at least one second protective portion and an end of the test pad along the first direction is greater than or equal to 0.5 um and less than or equal to 2 um.

7. The circuit board in accordance with claim 2, wherein the at least one second protective portion extends along a second direction intersecting the first direction.

8. The circuit board in accordance with claim 2, wherein the at least one second protective portion includes a plurality of protrusions, a third distance between the adjacent protrusions along a second direction intersecting the first direction is greater than or equal to 0.5 um and less than or equal to 158 mm.

9. The circuit board in accordance with claim 8, wherein a fourth distance between the adjacent protrusions along the first direction is greater than or equal to 0.5 um and less than or equal to 50 mm.

10. The circuit board in accordance with claim 2, wherein the at least one second protective portion includes a plurality of protrusions, and a fourth distance between the adjacent protrusions along the first direction is greater than or equal to 0.5 um and less than or equal to 50 mm.

11. The circuit board in accordance with claim 3, wherein the at least one second protective portion includes a plurality of protrusions, and a fourth distance between the adjacent protrusions along the first direction is greater than or equal to 0.5 um and less than or equal to 50 mm.

12. The circuit board in accordance with claim 2, wherein a top surface and a lateral surface of the third conductive section are covered by the at least one second protective portion, the surface of the substrate where is between the third conductive sections of the adjacent circuit lines are covered by the at least one second protective portion, a thickness of the at least one second protective portion covering the top surface of the third conductive section is greater than or equal to 0.5 um and less than or equal to 50 um.

13. The circuit board in accordance with claim 12, wherein each of the plurality of circuit lines includes a copper layer and a tin layer which is located between the copper layer and the at least one second protective portion.

14. The circuit board in accordance with claim 2, wherein a first edge of the at least one second protective portion is closer to the first protective portion than a second edge of the at least one second protective portion, a fifth distance from the first edge to the second edge is greater than or equal to 0.5 um and less than or equal to 50 mm.
